(19) United States
(12) Patent Application Publication
(10) Pub. No.: US 2016/0300960 A1
(43) Pub. Date: Oct. 13, 2016

(54) DIODE AND METHOD OF MANUFACTURING DIODE

(71) Applicants: TOYOTA JIDOSHA KABUSHIKI KAISHA, Toyota-shi (JP); DENSO CORPORATION, Kariya-shi (JP)

(72) Inventors: Hiroki MIYAKE, Toyota-shi (JP); Tatsuji NAGAOKA, Toyota-shi (JP); Shinichiro MIYAHARA, Kariya-shi (JP); Sachiko AOI, Nagakute-shi (JP)

(73) Assignees: TOYOTA JIDOSHA KABUSHIKI KAISHA, Toyota-shi (JP); DENSO CORPORATION, Kariya-shi (JP)

(21) Appl. No.: 15/092,929

(22) Filed: Apr. 7, 2016

(30) Foreign Application Priority Data
Apr. 9, 2015 (JP) 2015-080217

(51) Int. Cl. H01L 29/861; H01L 21/265; H01L 29/66

(52) U.S. Cl. CPC H01L 29/861; H01L 29/66136; H01L 21/26513

(57) ABSTRACT

A diode is provided with a semiconductor substrate; an anode electrode located on a front surface of the semiconductor substrate; and a cathode electrode located on a rear surface of the semiconductor substrate. Each of the p-type contact regions includes: a first region being in contact with the anode electrode; a second region located on the rear surface side of the first region, having a p-type impurity density lower than a p-type impurity density in the first region; and a third region located on the rear surface side of the second region and having a p-type impurity density lower than the p-type impurity density in the second region. A thickness of the second region is thicker than a thickness of the first region.

### CROSS-REFERENCE TO RELATED APPLICATION

This application claims priority to Japanese Patent Application No. 2015-080217 filed on Apr. 9, 2015, the entire contents of which are hereby incorporated by reference into the present application.

### TECHNICAL FIELD

The technique disclosed in this disclosure relates to a diode and a method of manufacturing a diode.

### DESCRIPTION OF RELATED ART

Japanese Patent Application Publication No. 2009-94433 discloses a diode provided with a plurality of p-type contact regions, n-type contact regions, and an n-type cathode region. Each n-type contact region is arranged between two p-type contact regions that are adjacent to each other. The p-type contact regions and the n-type contact regions make contact with an anode electrode. The cathode region is arranged on a rear surface side of the p-type contact regions and the n-type contact regions, and makes contact with a cathode electrode. An n-type impurity density of the n-type contact regions is low. A p-type impurity density of the p-type contact regions is high. When a reverse voltage is applied to this diode, a depletion layer spreads from the p-type contact regions to the n-type contact region. The n-type contact regions are thereby pinched off by the depletion layer. Due to this, a current does not flow in the diode during when the reverse voltage is applied. When a forward voltage is applied to the diode, holes flow into the p-type contact regions from the anode electrode. Accompanying the inflow of the holes into the p-type contact regions, the depletion layer recedes from each n-type contact region toward a p-type contact region side, and the depletion layer vanishes within the n-type contact region. Due to this, when the forward voltage is applied to the diode, the current flows from the anode electrode to the cathode electrode via the n-type contact regions. That is, the p-type contact regions do not become current passages, but instead the n-type contact regions become the current passages and the diode turns on. Notably, a barrier between the anode electrode and the p-type contact regions is small due to the high p-type impurity density of the p-type contact regions as described above. When the barrier between the anode electrode and the p-type contact regions is small as above, the holes are more prone to flowing in from the anode electrode to the p-type contact regions upon the forward voltage application, and the depletion layer vanishes from within the n-type contact regions in a short period of time. Due to this, such a diode has a fast response speed.

Further, Japanese Patent Application Publication No. 2013-120784 discloses a diode similar to that of Japanese Patent Application Publication No. 2009-94433, in which p-type contact regions are configured of a two-layer structure. In this diode, the p-type contact regions include a high density region provided in a range making contact with an anode electrode, and a low density region arranged on a rear surface side of the high density region. In the diode of Japanese Patent Application Publication No. 2013-120784 also, a barrier between the anode electrode and the p-type contact regions is small due to the high p-type impurity density of the high density region in contact with the anode electrode. Due to this, the diode of Japanese Patent Application Publication No. 2013-120784 also has a fast response speed.

### SUMMARY

The diode of Japanese Patent Application Publication No. 2009-94433 has high p-type impurity density in the p-type contact regions. Due to this, when a reverse voltage is applied to the diode, the n-type contact regions are depleted while the p-type contact regions are not depleted. Due to this, an electric field concentration occurs in a vicinity of ends of the p-type contact regions. Due to this, the diode of Japanese Patent Application Publication No. 2009-94433 has a low reverse-direction voltage resistance. Further, if the p-type impurity density of the p-type contact regions is made low in order to suppress the electric field concentration, the p-type contact regions are depleted upon the application of the reverse voltage. If the p-type contact regions are depleted, the depletion layer would not spread further into the n-type contact regions, as a result of which the pinch-off of the n-type contact regions becomes difficult.

In the diode of Japanese Patent Application Publication No. 2013-120784, the p-type contact regions include the high density region arranged on a front surface side and the low density region arranged on the rear surface side. Due to the low density region being depleted upon the application of the reverse voltage, the low density region hardly contributes to the depletion of the n-type contact regions. Due to this, the high density region needs to be made relatively thick to surely pinch off the n-type contact regions. The low density region is depleted when the reverse voltage is applied to the diode, but the high density region is not depleted. That is, upon the application of the reverse voltage, the high density region is not depleted, whereas the low density region and the n-type contact regions are depleted. Due to the non-depleting high density region being thick, the electric field concentration occurs in a vicinity of an end of the high density region upon the application of the reverse voltage. The diode of Japanese Patent Application Publication No. 2013-120784 also has a low reverse-direction voltage resistance.

Notably, the diodes of the aforementioned prior art publications are diodes of a type in which holes do not flow into n-type drift regions from the p-type contact regions upon its turn-on. Such a type of diode is called a JBSD (Junction Barrier Schottky Diode). On the other hand, there is also a type of diode in which the holes flow into the n-type drift regions from the p-type contact regions upon its turn-on (i.e., a type in which both electrons and holes contribute to the current). Such a type of diode is called an MPSD (Merged PIN Schottky Diode). A similar problem as that of the JBSD occurs in the MPSD. Thus, in the present disclosure, a technique that improves a reverse-direction voltage resistance in a diode having both p-type contact regions and an n-type contact region on a contact surface between a semiconductor substrate and an anode electrode is provided.

A diode disclosed herein comprises a semiconductor substrate; an anode electrode located on a front surface of the semiconductor substrate; and a cathode electrode located on a rear surface of the semiconductor substrate. The semiconductor substrate comprises a plurality of p-type contact regions, an n-type contact region, and an n-type cathode region. The plurality of p-type contact regions is in contact with the anode electrode. The n-type contact region is located between the adjacent p-type contact regions and is in contact with the anode electrode. The n-type cathode region is located on a rear surface side of the p-type contact regions and the n-type contact region and is in contact with the cathode electrode. Each of the p-type contact regions comprises first to third regions. The first region is in contact with the anode electrode. The second region is located on the rear surface side of the first region, and has a p-type impurity density lower than a p-type impurity density in the first region. The p-type impurity density in the second region is distributed within a range from minus 30% to plus 30% with respect to an average value of the p-type impurity density in the second region. The third region is located on the rear surface side of the second region and has a p-type impurity density lower than the p-type impurity density in the second region. A thickness of the second region is thicker than a thickness of the first region.

The diode comprises the p-type contact regions, including the first region having the high p-type impurity density, the second region having the medium p-type impurity density, and the third region having the low p-type impurity density. In the second region, the p-type impurity density is distributed within the range from minus 30% to plus 30%, meaning that a difference in the p-type impurity density is small. Further, the second region is thicker than the first region. That is, in this diode, the second region in which the p-type impurity density is distributed at a medium degree is thick. The first region having the high p-type impurity density is provided by making its barrier between the anode electrode and the p-type contact regions small so as to increase a response speed of the diode. When a reverse voltage is applied to this diode, a depletion layer spreads from the p-type contact regions to the n-type contact region, as a result of which the n-type contact region is pinched off. Here, the third region with the low p-type impurity density hardly contributes to the spreading of the depletion layer to the n-type contact region since the third region is instantly depleted, however, the first region having the high p-type impurity density and the second region having the medium p-type impurity density contribute to the spreading of the depletion layer to the n-type contact region. Further, although a thickness of the first region is thin, the n-type contact region can surely be pinched off due to the thickness of the second region being thick. Further, when the reverse voltage is applied, the third region having the low p-type impurity density is depleted. Further, when even a higher reverse voltage is applied, the second region having the medium p-type impurity density is depleted in addition to the third region. The first region having the high p-type impurity density will not be depleted. However, since the thickness of the first region is thin, an electric field concentration is less likely to occur at an end of the first region even though the first region is not depleted. That is, the diode suppresses the electric field concentration even when the high reverse voltage is applied. Accordingly, the diode has a high reverse-direction voltage resistance. As described above, the reverse-direction voltage resistance of the diode can be improved by providing the thick second region with a small difference in the p-type impurity density.

In another aspect of the present disclosure, a method for manufacturing a diode is provided, the method comprising first to fourth processes. In the first process, p-type impurities are implanted with a first density to a plurality of ranges in a front surface of an n-type semiconductor substrate so that the p-type impurities stop at a first depth, wherein the ranges are arranged at intervals in the front surface. In the second process, the p-type impurities are implanted with a second density to the plurality of ranges so that the p-type impurities stop in a depth range deeper than the first depth, the second density being lower than the first density. The implanting for the p-type impurities with the second density includes a plurality of implantations in which the p-type impurities stop at a plurality of depths in the depth range. In the third process, an anode electrode is formed so as to be in contact with the front surface including the plurality of ranges. In the fourth process, a cathode electrode is formed on a rear surface of the semiconductor substrate.

The processes described above are not limited to the order by which they are described.

In this method, the first region with the high p-type impurity density can be formed by the first process. Further, the second region with the small difference in the p-type impurity density and the thin thickness located on the rear surface side of the first region can be formed by the second process. Further, the third region with the low p-type impurity density positioned on the rear surface side of the second region is formed by diffusing a part of the p-type impurities implanted in the second implanting to the deeper side. Notably, another process for implanting the p-type impurities at a low density to the third region may further be provided. According to this method, a diode having the high reverse-direction voltage resistance can be manufactured.

### BRIEF DECRIPTION OF DRAWINGS

FIG. 1 is a vertical cross sectional view of a diode 10 (a vertical cross sectional view along a line I-I in FIG. 2);

FIG. 2 is a plan view showing a front surface 12a of a semiconductor substrate 12;

FIG. 3 is an enlarged cross sectional view of p-type contact regions 20 and n-type contact regions 25;

FIG. 4 is a graph showing a p-type impurity density distribution in each p-type contact region 20;

FIG. 5 is an enlarged cross sectional view of a potential distribution when a reverse voltage is applied to the diode 10;

FIG. 6 is an enlarged cross sectional view of a potential distribution when a reverse voltage is applied to a diode of a comparative example;

FIG. 7 is an explanatory diagram of a method of manufacturing the diode 10;

FIG. 8 is an enlarged cross sectional view of a diode of a first variant; and

FIG. 9 is an enlarged cross sectional view of a diode of a second variant.

### DETAILED DESCRIPTION

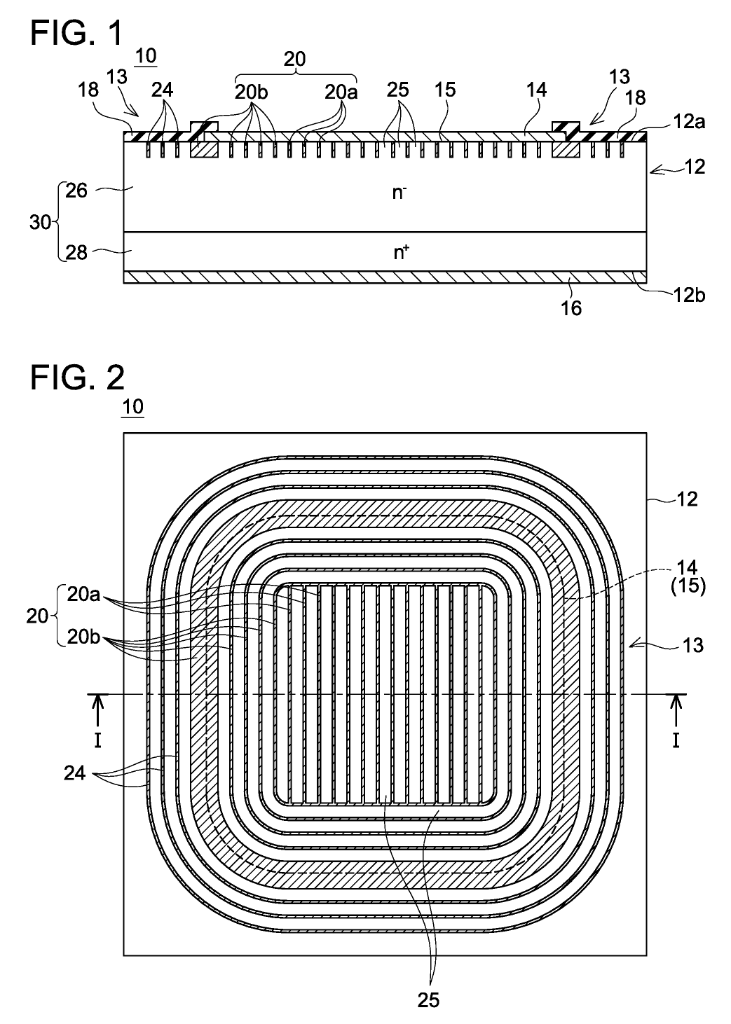

A diode 10 of an embodiment shown in FIGS. 1 and 2 comprises a semiconductor substrate 12. Notably in FIG. 2, a p-type region is shown by oblique hatched lines. The semiconductor substrate 12 is configured of a wide-gap semiconductor (e.g., SiC). An anode electrode 14 and an insulating film 18 are provided on a front surface 12a of the semiconductor substrate 12. A dotted line 14 in FIG. 2 shows a contour of a range where the anode electrode 14 is provided (i.e., a contact surface 15 where the semiconductor substrate 12 and the anode electrode 14 make contact). The anode electrode 14 is provided at a center portion of the front surface 12a of the semiconductor substrate 12. A region on the front surface 12a that is not covered by the anode electrode 14 (i.e., a region on an outer side of the dotted line 14; hereafter termed a peripheral region 13) is covered by the insulating film 18. A cathode electrode 16 is provided on a rear surface 12b of the semiconductor substrate 12.

An n-type region and a p-type region are provided within the inside of the semiconductor substrate 12. The p-type region comprises p-type contact regions 20 making contact with the anode electrode 14, and FLRs 24 not making contact with the anode electrode 14. As shown in FIG. 1, the p-type region is provided only on a front layer portion in a vicinity of the front surface 12a of the semiconductor substrate 12. The n-type region encompasses most part of the semiconductor substrate 12.

The p-type contact regions 20 comprise stripe-shaped p-type contact regions 20a and ring-shaped p-type contact regions 20b. As shown in FIG. 2, the stripe-shaped p-type contact regions 20a and the ring-shaped p-type contact regions 20b are provided within the contact surface 15 in the front surface 12a of the semiconductor substrate 12. Each of the p-type contact regions 20 makes contact with the anode electrode 14. The FLRs 24 are provided on the outer side of the contact surface 15 within the front surface 12a of the semiconductor substrate 12. That is, the FLRs 24 are provided within the peripheral region 13. Upper surfaces of the FLRs 24 are covered by the insulating film 18.

As shown in FIG. 2, each of the ring-shaped p-type contact regions 20b extends in a ring shape within the contact surface 15. The plurality of ring-shaped p-type contact regions 20b is arranged at intervals from an outer peripheral side toward an inner peripheral side. The ring-shaped p-type contact region 20b on the outermost peripheral side has a wider width than the other ring-shaped p-type contact regions 20b. The ring-shaped p-type contact region 20b on the outermost peripheral side has its portion on the inner peripheral side than its width center positioned within the contact surface 15, and has its portion on the outer peripheral side than its width center located outside the contact surface 15. Other ring-shaped p-type contact regions 20b have their entirety located within the contact surface 15.

As shown in FIGS. 1 and 2, the stripe-shaped p-type contact regions 20a are provided on an inner peripheral portion of the ring-shaped p-type contact region 20b on the innermost peripheral side. Each of the stripe-shaped p-type contact regions 20a extends linearly in parallel to each other. The stripe-shaped p-type contact regions 20a are connected to the ring-shaped p-type contact region 20b on the innermost peripheral side at their both ends.

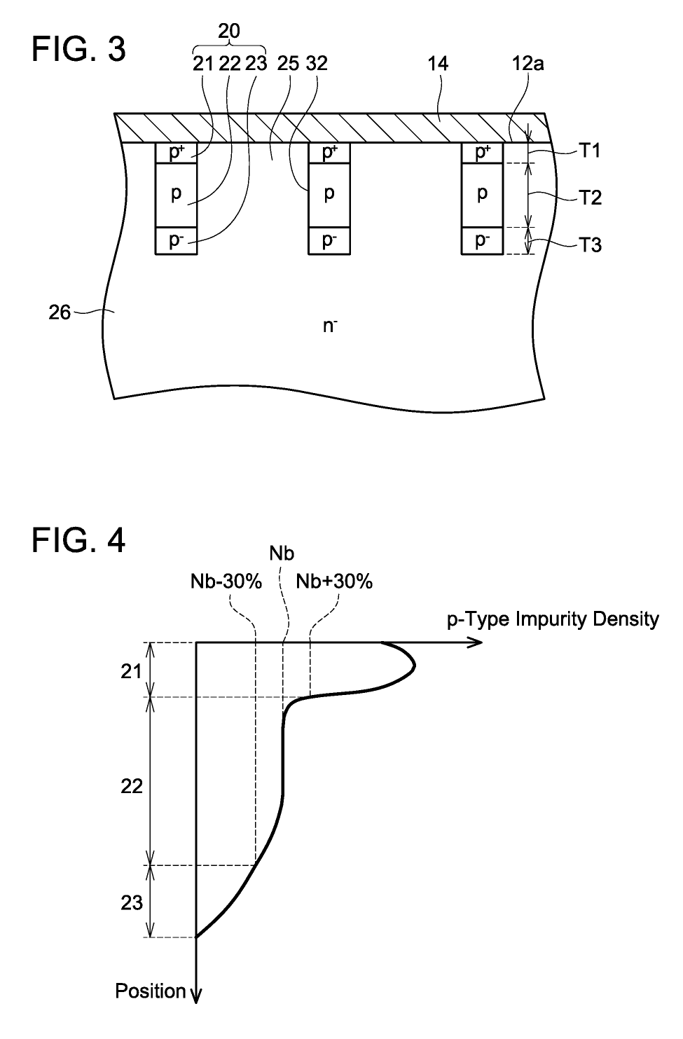

FIG. 3 shows an enlarged cross sectional view of the p-type contact regions 20. Each p-type contact region 20 (i.e., each of the stripe-shaped p-type contact regions 20a and each of the ring-shaped p-type contact regions 20b) comprises a three-layer structure including a first region 21, a second region 22, and a third region 23. The first regions 21 are exposed on the front surface 12a of the semiconductor substrate 12, and make contact with the anode electrode 14. The second regions 22 are located under the corresponding first regions 21. The third regions 23 are located under the corresponding second regions 22. FIG. 4 shows a p-type impurity density distribution in the depth direction (thickness direction of the semiconductor substrate 12) in each of the p-type contact regions 20. As shown in FIG. 4, the p-type impurity density in the first region 21 is high. The p-type impurity density in the second region 22 is lower than the p-type impurity density in the first region 21. The p-type impurity density in the third region 23 is lower than the p-type impurity density in the second region 22. Further, the p-type impurities are distributed at substantially uniform density within the second region 22. An average value of the p-type impurity density in the second region 22 is at a density Nb. The density Nb is preferably a value within a range of 1×10¹⁷ to 1×10¹⁸ atoms/cm³. The second region 22 is a region in which the p-type impurity density is distributed within a range of minus 30% to plus 30% of the density Nb. The first region 21 is a region having a p-type impurity density that is equal to or greater than 1.3 times the density Nb (Nb+30%). The third region 23 is a region having a p-type impurity density that is equal to or less than 0.7 times the density Nb (Nb−30%). As shown in FIGS. 3 and 4, a thickness T2 of the second region 22 is thicker than both a thickness T1 of the first region 21 and a thickness T3 of the third region 23. However, the thickness T3 may be thicker than the thickness T2. The thickness T1 is preferably 0.4 μm or less. The thickness T2 is preferably in a range of 0.3 to 0.5 μm. The thickness T3 is preferably in a range of 0.3 to 0.5 μm.

The FLRs 24 are p-type semiconductor regions. Each of the FLRs 24 is provided in the peripheral region 13, and extends in a ring shape so as to surround a periphery of the anode electrode 14.

The n-type region comprises n-type contact regions 25 and a cathode region 30.

Each of the n-type contact regions 25 is provided in a range between two adjacent p-type contact regions 20. Each n-type contact region 25 makes contact with the p-type contact regions 20 on its both sides. The n-type contact regions 25 make contact with the first regions 21, the second regions 22, and the third regions 23. An n-type impurity density of the n-type contact regions 25 is low, and in the present embodiment, it is 9. 5×10¹⁵ atoms/cm³ or less. The n-type contact regions 25 make contact with the anode electrode 14. The n-type contact regions 25 forms Schottky contacts with the anode electrode 14.

The cathode region 30 is provided under the p-type contact regions 20 and the n-type contact regions 25. The cathode region 30 is continuously connected to each of the n-type contact regions 25. Further, the cathode region 30 makes contact with lower ends of the p-type contact regions 20. The cathode region 30 extends to the rear surface 12b of the semiconductor substrate 12, and makes contact with the cathode electrode 16. Further, the cathode region 30 is provided also under the FLRs 24. The cathode region 30 comprises a drift region 26 and a cathode contact region 28.

The n-type impurity density of the drift region 26 is low, and in the present embodiment, it is 9.5×10¹⁵ atoms/cm³ or less. The n-type impurity density of the drift region 26 is substantially equal to the n-type impurity density of the n-type contact regions 25. The drift region 26 is provided at a location where it is vertically adjacent to the p-type contact regions 20, the n-type contact regions 25, and the FLRs 24.

The cathode contact region 28 has a higher n-type impurity density than the n-type impurity density of the drift region 26. In the present embodiment, the n-type impurity density of the cathode contact region 28 is equal to or more than 3.0×10¹⁸ atoms/cm³. The cathode contact region 28 is provided under the drift region 26. The cathode contact region 28 is provided in a range in the semiconductor substrate 12 that is exposed on the rear surface 12b. The cathode contact region 28 makes an ohmic contact with the cathode electrode 16. The cathode contact region 28 is separated by the drift region 26 from the p-type contact regions 20, the n-type contact regions 25, and the FLRs 24.

Next, an operation of the diode 10 will be described. In a state where a reverse voltage (i.e., a potential by which the cathode electrode 16 comes to be at a higher potential than the anode electrode 14) is applied to the diode 10, a depletion layer spreads over the p-type contact regions 20 and the n-type contact regions 25. The n-type contact regions 25 are depleted entirely along their width direction. Further, entireties of the second regions 22 and the third regions 23 of the p-type contact regions 20 are depleted. The first regions 21 are only partially depleted, and their most portions are not depleted. Then, when a forward voltage is applied to the diode 10, holes flow in from the anode electrode 14 to the p-type contact regions 20. The depletion layer shrinks with the inflow of the holes into the p-type contact regions 20. More specifically, the depletion layer in each n-type contact region 25 recedes toward pn junctions 32 at interfaces between the n-type contact region 25 and the p-type contact regions 20. As a result, the depletion layer vanishes from within the n-type contact region 25. Further, the depletion layer in each p-type contact region 20 recedes toward the pn junctions 32. As a result, the depletion layer vanishes from within the p-type contact region 20. When the depletion layer in the n-type contact regions 25 vanishes, electrons flow from the drift region 26 to the anode electrode 14 through the Schottky interfaces between the anode electrode 14 and the n-type contact regions 25. That is, the electrons flow from the cathode electrode 16 to the anode electrode 14 through the cathode contact region 28, the drift region 26, and the n-type contact regions 25. Due to this, the diode 10 turns on. Notably, since the p-type impurity density of the first region 21 is high, the barrier between the first region 21 and the anode electrode 14 is small. Due to this, when the diode turns on, the holes flow in easily from the anode electrode 14 to the p-type contact regions 20. Due to this, when the diode turns on, the depletion layer vanishes at a fast speed from within the n-type contact regions 25 and the p-type contact regions 20. Due to this, this diode has a fast response speed. Further, in the diode 10, no current flows in the p-type contact regions 20 when the diode is on. That is, the diode 10 is a JBSD.

Thereafter, when the reverse voltage is applied to the diode 10, the depletion layer spreads from the pn junctions 32 to the n-type contact regions 25 and the p-type contact regions 20. The depletion layer spreads in each n-type contact region 25 from the p-type contact regions 20 on its both sides (i.e., the pn junctions 32 on the both sides). Depletion layers that spread from the both sides into the n-type contact region 25 are connected within the n-type contact region 25. That is, the n-type contact region 25 is depleted over its entirety in the width direction. Accordingly, with the n-type contact regions 25 pinched off by the depletion layer, the current that had been flowing in the n-type contact regions 25 stops, and the diode 10 is turned off. At this occasion, the entireties of the third regions 23 are instantly depleted by the depletion layers extending from the pn junctions 32 due to the low p-type impurity density in the third regions 23. Due to this, the third regions 23 hardly contribute to the spreading of the depletion layer in the n-type contact regions 25. The first regions 21 are only partially depleted, since the first regions 21 have high p-type impurity density. Further, the second regions 22 are not instantly depleted, because the second regions 22 have relatively high p-type impurity density. Due to this, the first regions 21 and the second regions 22 contribute to the spreading of the depletion layer in the n-type contact regions 25. Further, to pinch off the n-type contact regions 25, the p-type regions contributing to the spreading of the depletion layer in the n-type contact regions 25 need to have a certain thickness in the thickness direction of the semiconductor substrate 12. In the present embodiment, a thickness T1 of the first regions 21 is thin, but a thickness T2 of the second regions 22 is thick. Due to this, the n-type contact regions 25 are pinched off by the depletion layer spreading from the first regions 21 and the second regions 22.

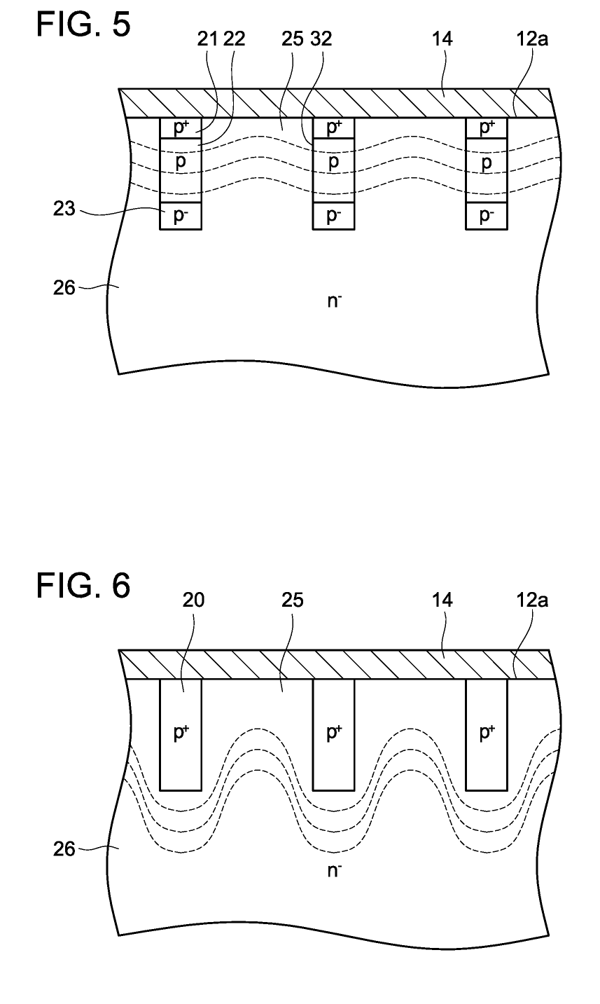

Further, when the reverse voltage further increases after the n-type contact regions 25 have been depleted, the entireties of the second regions 22 are depleted by the depletion layer spreading from the pn junctions 32. Dotted lines in FIG. 5 show potential distributions when the second regions 22 are depleted. When the second regions 22 are depleted, the first regions 21 are the only regions in a vicinity of the anode electrode 14 that have not yet been depleted. The first regions 21, which have not been depleted, are in a state of protruding out in depleted regions. Due to this, electric field concentrates in a vicinity of lower ends of the first regions 21 (especially in a vicinity of corners of the lower ends). However, as described above, the thickness T1 of the first regions 21 is thin. That is, an amount by which the non-depleted first regions 21 protrude out in the depleted regions is small. Due to this, the electric field is prevented from concentrating in the vicinity of the lower ends of the first regions 21. FIG. 6 shows potential distributions in a case where entireties of p-type contact regions 20 have a high p-type impurity density (i.e., a case where substantial entireties of the p-type contact regions 20 are not depleted) as a comparative example. As shown in FIG. 6, when a thickness of the non-depleted p-type contact regions 20 is thick, equipotential lines in a vicinity of corners of lower ends of the p-type contact regions 20 become dense, and a high electric field is generated in such a region. Contrary to this, as shown in FIG. 5, in the diode 10 of the present embodiment, such a high electric field is less likely to occur in the vicinity of the lower ends of the first regions 21 due to the thickness TI of the non-depleted first regions 21 being thin. Due to this, the diode 10 of the present embodiment achieves a high reverse-direction voltage resistance.

Further, when the second regions 22 and the third regions 23 under the first regions 21 are depleted, a leak current is prevented from flowing through the first regions 21 when the reverse voltage is applied. Especially, since the second regions 22 with the thick thickness T2 are depleted, the leak current can effectively be suppressed in the diode 10.

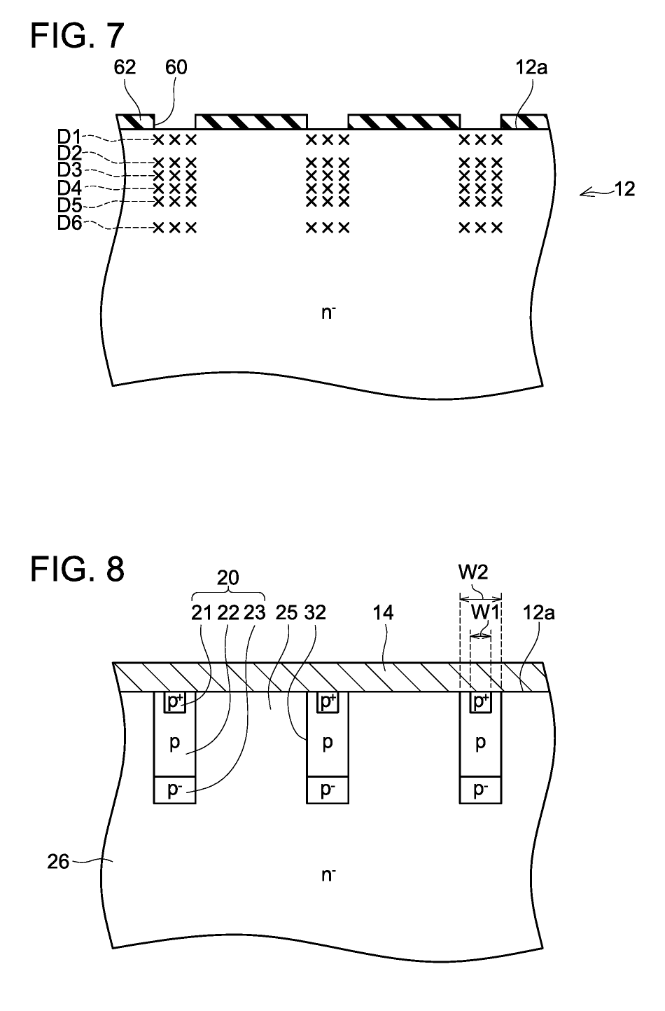

Next, a method of manufacturing the diode 10 will be described. The diode 10 is manufactured from an n-type semiconductor substrate 12 (unprocessed semiconductor substrate 12) having substantially the same n-type impurity density as the drift region 26. Firstly, as shown in FIG. 7, a mask 62 having openings 60 is formed on the front surface of the semiconductor substrate 12. The openings 60 are formed to be positioned over regions where the p-type contact regions 20 are to be formed, and regions where the FLRs 24 are to be formed. Next, p-type impurity ions are irradiated onto the front surface 12a of the semiconductor substrate 12. The irradiated p-type impurity ions are implanted to the front surface 12a of the semiconductor substrate 12 inside the openings 60. Here, first to third implantation steps are performed.

In the first implantation step, the p-type impurities are irradiated at low irradiation energy over a long period of time. Due to this, the p-type impurities are implanted at a high density at a depth D1 of FIG. 7 (i.e., a front-most layer portion).

In the second implantation step, the p-type impurities are irradiated for plural times by changing the irradiation energy. Due to this, the p-type impurities are implanted at depths D2, D3, D4, D5 of FIG. 7 (i.e., a depth range deeper than the depth D1). Here, the implantation is performed by shortening irradiation time than in the first implantation step so that the p-type impurity densities in the respective depths D2, D3, D4, D5 become lower than the p-type impurity density in the depth D1. Further, the implantation is performed so that the p-type impurity densities in the respective depths D2, D3, D4, D5 become substantially the same.

In the third implantation step, the p-type impurities are irradiated with high irradiation energy for a short period of time. Due to this, the p-type impurities are implanted at a low density at a depth D6, which is deeper than the depth D5.

Next, the p-type impurities implanted in the semiconductor substrate 12 are activated by annealing the semiconductor substrate 12. When the annealing is performed, the p-type impurities are diffused in the semiconductor substrate 12. Due to this, the p-type impurities are distributed according to the distribution shown in FIG. 4. That is, the first regions 21 are formed at the depth where the p-type impurities were implanted in the first implantation step. The second regions 22 are formed at the depth where the p-type impurities were implanted in the second implantation step. The third regions 23 are formed at the depth where the p-type impurities were implanted in the third implantation step. Since the p-type impurities were implanted in the second implantation step at substantially the same density to plural depths, the second regions 22 are formed with substantially uniform p-type impurity density and with the thick thickness T2.

Thereafter, the diode 10 as shown in FIGS. 1 to 3 is completed by forming the anode electrode 14, the insulating film 18, the cathode contact region 28, and the cathode electrode 16.

Notably, in the above method of manufacture, the p-type impurities are implanted at the depth D6 in the third implantation step. Alternatively, the third implantation step may not be performed. Even in such a configuration, the third regions 23 may be formed by the p-type impurities implanted in the second implantation step being dispersed during the annealing.

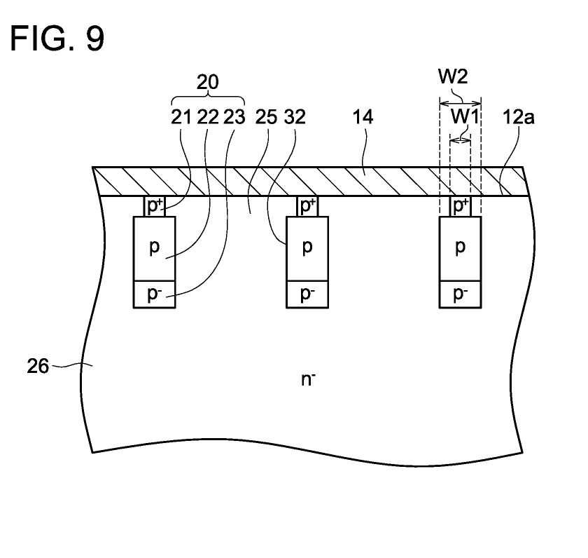

Further, in the aforementioned embodiment, the first regions 21 have substantially the same width as the second regions 22. Alternatively, as shown in FIGS. 8 and 9, a width W1 of the first regions 21 may be narrower than a width W2 of the second regions 22.

Further, in the diode 10 of the aforementioned embodiment, the holes do not flow into the cathode region 30 from the p-type contact regions 20 when the diode is on. Alternatively, the holes may flow into the cathode region 30 from the p-type contact regions 20 when the diode is on. That is, the diode may be a MPSD.

Some of the technical elements disclosed in the description are listed herein below. Notably, each of the below technical elements is individually useful.

In a diode disclosed herein as an example, the thickness of the second region may he thicker than a thickness of the third region.

In a diode disclosed herein as an example, a width of the first region may be narrower than a width of the second region.

Specific examples of the present invention has been described in detail, however, these are mere exemplary indications and thus do not limit the scope of the claims. The art described in the claims include modifications and variations of the specific examples presented above. Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

What is claimed is:

1. A diode comprising:
a semiconductor substrate;
an anode electrode located on a front surface of the semiconductor substrate; and
a cathode electrode located on a rear surface of the semiconductor substrate,
wherein
the semiconductor substrate comprises:
a plurality of p-type contact regions being in contact with the anode electrode;
an n-type contact region located between the adjacent p-type contact regions and being in contact with the anode electrode; and
an n-type cathode region located on a rear surface side of the p-type contact regions and the n-type contact region and being in contact with the cathode electrode,
each of the p-type contact regions comprises:
a first region being in contact with the anode electrode;
a second region located on the rear surface side of the first region, having a p-type impurity density lower than a p-type impurity density in the first region, wherein the p-type impurity density in the second region is distributed within a range from minus 30% to plus 30% with respect to an average value of the p-type impurity density in the second region; and
a third region located on the rear surface side of the second region and having a p-type impurity density lower than the p-type impurity density in the second region, and
a thickness of the second region is thicker than a thickness of the first region.

2. The diode of claim 1, wherein the thickness of the second region thicker than a thickness of the third region.

3. The diode of claim 1, wherein a width of the first region is narrower than a width of the second region.

4. A method for manufacturing a diode, the method comprising:
implanting p-type impurities with a first density to a plurality of ranges in a front surface of an n-type semiconductor substrate so that the p-type impurities stop at a first depth, wherein the ranges are arranged at intervals in the front surface;
implanting the p-type impurities with a second density to the plurality of ranges so that the p-type impurities stop in a depth range deeper than the first depth, the second density being lower than the first density, wherein the implanting for the p-type impurities with the second density includes a plurality of implantations in which the p-type impurities stop at a plurality of depths in the depth range;
forming an anode electrode so as to be in contact with the front surface including the plurality of ranges; and
forming a cathode electrode on a rear surface of the semiconductor substrate.

5. The method of claim 4, further comprising implanting the p-type impurities with a third density to the plurality of ranges so that the p-type impurities stop at a depth deeper than the depth range, the third density being lower than the second density.
